(19) United States
(12) Patent Application Publication
(10) Pub. No.: US 2023/0106834 A1
(43) Pub. Date: Apr. 6, 2023

(54) METHOD OF MANUFACTURING OPTOELECTRONIC PRODUCTS AND APPARATUS THEREOF

(71) Applicant: EPISTAR CORPORATION, Hsinchu (TW)

(72) Inventor: Min-Hsun HSIEH, Hsinchu (TW)

(21) Appl. No.: 17/958,667

(22) Filed: Oct. 3, 2022

Related U.S. Application Data
(60) Provisional application No. 63/252,550, filed on Oct. 5, 2021.

(30) Foreign Application Priority Data
Jun. 1, 2022 (TW) 111120508

(51) Int. Cl. H01L 33/00

(52) U.S. Cl. CPC H01L 33/0093; H01L 2933/0041

(57) ABSTRACT

The application provides a method of manufacturing optoelectronic products. A first carrier substrate is provided with electronic devices arranged as a first matrix with a first row pitch and a first column pitch. A first transferring step is performed to transfer a first portion of the electronic devices from the first carrier substrate to a second carrier substrate to form a second matrix with a second row pitch equal to the first row pitch and a second column pitch larger than the first column pitch. A second transferring step is performed to transfer a second portion of the electronic devices from the second carrier substrate to a third carrier substrate to form a third matrix with a third row pitch larger than the second row pitch and a third column pitch equal to the second column pitch.

### CROSS REFERENCE TO RELATED APPLICATIONS

This application claims the benefit of U.S. Provisional Application No. 63/252,550, filed on Oct. 5, 2021, and also claims priority of Taiwan Patent Application No. 111120508, filed on Jun. 1, 2022, the entireties of which are incorporated by reference herein.

### BACKGROUND

### Technical Field

The application relates to a method for manufacturing optoelectronic products and apparatus thereof. In particular, to a method for manufacturing LED devices, such as LED screens, and apparatus thereof.

### Description of the Related Art

A light-emitting diode (LED) is an optoelectronic semiconductor device that is suitable for diverse lighting and display applications because it has good characteristics, including low power consumption, low heat generation, long operation life, shock tolerance, a compact size, and swift response.

Semiconductor manufacturing technology has made continuous progress, and once the size of LED chips becomes too small to be visible to the naked eye, e.g., less than 100 μm, less than 50 μm, and less than 30 μm, the potential application for LED chips was no longer limited to serving as the backlight source in liquid-crystal displays. Red, blue, and green LED chips can directly form a pixel in a display, suggesting that color filters and liquid-crystal layers in liquid-crystal displays are not necessary anymore. The LED chips themselves emit light, and thus no additional backlight modules are required.

However, for a 75-inch LED display with 4K resolution, about 24 million LED chips are required. To transfer millions even tens of millions of LED chips from growth substrates or temporary substrates to the backplane of a display in order, a technique called mass transfer is required. One of the endeavors in the industry is to reach the goal of performing such a mass transfer efficiently, and with high accuracy, high yield, and low cost.

### BRIEF SUMMARY OF THE DISCLOSURE

An embodiment of the application discloses a method for manufacturing an optoelectronic device. The method provides one first carrier substrate and a plurality of electronic devices disposed thereon and arranged as a first matrix having first columns along a first direction and first rows along a second direction. Two adjacent first columns are separated from each other by a first column pitch, and two adjacent first rows are separated from each other by a first row pitch. The method further transfers a first portion of the electronic devices from the first carrier substrate to a second carrier substrate and arranges the electronic devices as a second matrix having second columns along the first direction and second rows along the second direction. Two adjacent second columns are separated from each other by a second column pitch, and two adjacent second rows are separated from each other by a second row pitch. The second column pitch is equal to the first column pitch, and the second row pitch is greater than the first row pitch. The method further transfers a second portion of the electronic devices from the second carrier substrate to a third carrier substrate and arranges the electronic devices in a third matrix having third columns along the first direction and third rows along the second direction. Two adjacent third columns are separated from each other by a third column pitch, and two adjacent third rows are separated from each other by a third row pitch. The third column pitch is greater than the second column pitch, and the third row pitch is equal to the second row pitch.

An embodiment of the application discloses an apparatus for performing the step of transferring a plurality of electronic devices in the method in the previous section. The apparatus includes a laser module, a donor stage, and a receiving stage. The laser module is configured to generate a laser beam. The donor stage is configured to support the first carrier substrate and the plurality of electronic devices on the first carrier substrate. The laser module and the donor stage are configured to allow relative movement, thereby enabling the laser beam to irradiate the first portion of the electronic devices among the electronic devices. The receiving stage is configured to support the second carrier substrate. The donor stage and the receiving stage are configured to allow relative movement, thereby enabling the first portion of the electronic devices to be transferred to predetermined positions on the second carrier substrate.

An embodiment of the application discloses a method for manufacturing LED devices. The method includes providing a growth substrate and a plurality of LED chips formed thereon; transferring the LED chips from the growth substrate to a temporary substrate; forming a light conversion layer on the temporary substrate, wherein the light conversion layer covers the LED chips and is configured to convert a first light emitted from the LED chips into a second light with a predetermined wavelength; patterning the light conversion layer; forming a light filter layer on the light conversion layer, wherein the light filter layer covers the light conversion layer and the LED chips and is configured to block the first light; and patterning the light filter layer such that each LED device has the light conversion layer, the light filter layer, and one of the LED chips.

### BRIEF DESCRIPTION OF THE DRAWINGS

FIG. 1A is a manufacturing method according to an embodiment of the application.

FIG. 1B shows three carrier substrates sequentially formed by the manufacturing method in FIG. 1A.

FIG. 1C shows a screen formed of several pixel carrier substrates according to an embodiment of the application.

FIG. 1D shows another screen formed of several pixel carrier substrates according to an embodiment of the application.

FIG. 2A shows a growth substrate with LED devices formed thereon.

FIGS. 2B and 2C are cross-sectional views along lines BB and CC in FIG. 2A, respectively.

FIG. 3A shows LED devices in a specific exposure region on the growth substrate in FIG. 2A being irradiated by a laser beam.

FIG. 3B shows the LED devices in FIG. 2B being ablated from the growth substrate.

FIG. 3C shows transfer of one LED device in the specific exposure region in FIG. 2C to a carrier substrate.

FIG. 3D shows the LED devices in FIG. 2B being ablated from the growth substrate.

FIG. 3E shows transfer of one LED device in the specific exposure region in FIG. 2C to the carrier substrate.

FIG. 4 shows a laser transfer apparatus according to an embodiment of the application.

FIGS. 5A-5E show a process of transferring LED devices from the growth substrate to the carrier substrate by a pickup tool according to an embodiment of the application.

FIG. 6A shows transfer of LED devices on the growth substrate to a carrier substrate according to an embodiment of the application.

FIG. 6B shows sequential transfer of LED devices in several blocks of the growth substrate to the carrier substrate according to an embodiment of the application.

FIGS. 7A and 7B are cross-sectional views of the process of transferring LED devices from the growth substrate to a temporary substrate according to an embodiment of the application.

FIG. 8 shows the temporary substrate with LED devices disposed thereon.

FIGS. 9A-9C show the packaging process of the LED devices on the temporary substrate.

FIGS. 10A and 10B are cross-sectional views of two-pixel package structures.

FIG. 11 is a cross-sectional view of a pixel package structure according to another embodiment of the application.

FIGS. 12A-12D are cross-sectional views of the process for the pixel package structures of FIG. 11.

FIG. 13A is a cross-sectional view of LED devices formed on the growth substrate.

FIG. 13B is a cross-sectional view of a pixel package structure having the LED devices in FIG. 13A.

### DETAILED DESCRIPTION OF THE DISCLOSURE

Exemplary embodiments of the present application will be described in detail with reference to the accompanying drawings hereafter. The following embodiments are given by way of illustration to help those skilled in the art fully understand the spirit of the present application. Hence, it should be noted that the present application is not limited to the embodiments herein and can be realized by various forms. In the disclosure, the same reference numerals denote elements with the same or like structure, function, or principle, which may be conceived by a person skilled in the art according the teaching of the disclosure. The same elements with the same reference numeral will not described again for brevity.

In the embodiments of the application, a first carrier substrate is provided with LED devices arranged thereon in several columns and rows. The LED devices are arranged as a first matrix having first columns and first rows. Each two adjacent first columns in the first matrix are separated from each other by a first column pitch. Each two adjacent first rows in the first matrix are separated from each other by a first row pitch. The LED devices are subjected to a first transfer process to be transferred from the first carrier substrate to a second carrier substrate and be arranged as a second matrix. The second matrix has second columns and second rows. After the first transfer process, each two adjacent second columns in the second matrix are separated from each other by a second column pitch that is greater than the first column pitch in the first matrix; each two adjacent second rows are separated from each other by a second row pitch in the second matrix that is equal to the first row pitch in the first matrix. Next, the LED devices are subjected to a second transfer process to be transferred from the second carrier substrate to a third carrier substrate and be arranged as a third matrix. The third matrix has third columns and third rows. After the second transfer process, each two adjacent third columns in the third matrix are separated from each other by a third column pitch that is equal to the second column pitch in the second matrix; each two adjacent third rows are separated from each other by a third row pitch in the third matrix that is greater than the second row pitch in the second matrix. Finally, in terms of the matrix, the third column pitch in the third matrix is greater than the first column pitch in the first matrix, and the third row pitch in the third matrix is greater than the first row pitch in the first matrix because the first transfer process expands the first column pitch and the second transfer process expands the first row pitch.

In another embodiment, the first transfer process expands the first row pitch and the second transfer process expands the first column pitch. Eventually, in terms of the matrix, the third column pitch is greater than the first column pitch and the third row pitch is greater than the first row pitch.

In one embodiment, the third column pitch and the third row pitch on the third carrier substrate may be approximately equal to pixel column pitches and pixel row pitches on another pixel carrier substrate. Therefore, the LED devices on the third carrier substrate may be concomitantly transferred to another pixel carrier substrate so as to accelerate mass production of pixel carriers with LED devices thereon.

The first column pitch and the first row pitch on the first carrier substrate may be minimized as much as the manufacturing process can to maximize the number of the LED devices per unit area on the first carrier substrate. Accordingly, utilization of the first carrier substrate may increase. Moreover, in some embodiments, prior to transferring the LED devices, a portion of the LED devices may be processed directly on the first carrier substrate, thereby reducing material consumption during the manufacturing process. The detail regarding reduction of the material consumption will be described in the following paragraph of the description.

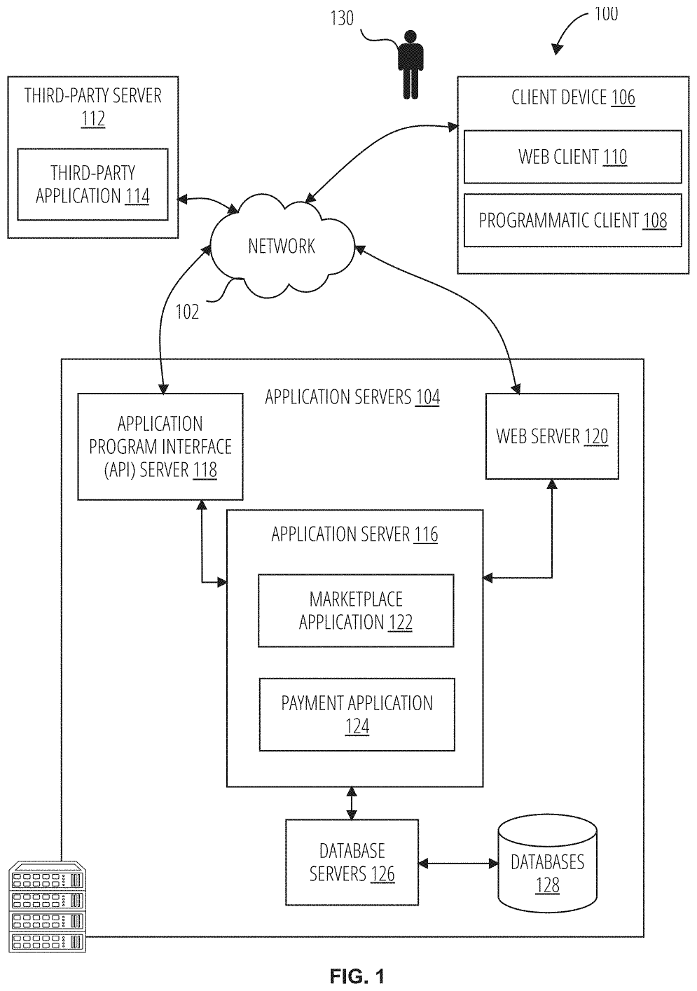

Referring to FIGS. 1A and 1B, FIG. 1A is a manufacturing method M01 according to an embodiment of the application, and FIG. 1B shows carrier substrates 100, 120, and 140 sequentially formed by the manufacturing method M01. There are two transfer processes of the LED devices in the manufacturing method M01. One transfer process transfers the LED devices from the carrier substrate 100 to the carrier substrate 120, and another transfer process transfers the LED devices from the carrier substrate 120 to the carrier substrate 140.

The step S02 of the manufacturing method M01 starts with providing the carrier substrate 100. As shown in FIG. 1B, LED devices 102 are disposed on the carrier substrate 100. For example, the LED devices 102 may be LED chips, which may have a single light-emitting region or multiple light-emitting regions. The light-emitting regions in the LED chips having multiple light-emitting regions may be connected in series, in parallel, or in parallel and series. An LED chip with multiple light-emitting regions connected in series may be referred to as a high voltage chip. In some other embodiments, the LED devices 102 may be also replaced with laser diodes, photodiodes, or integrated circuit components.

On the carrier substrate 100, LED devices 102 are arranged as a matrix 101 having columns X01-X05 extending along a vertical direction and rows Y01-Y08 extending along a horizontal direction. For example, FIG. 1B shows that there are column pitches 104H between the columns X01 and X02 and between the columns X02 and X03, and that there are row pitches 104V between the rows Y04 and Y05 and between the rows Y05 and Y06. In FIG. 1B, although all column pitches 104H on the carrier substrate 100 are substantially equal, and all row pitches 104V on the carrier substrate 100 are substantially equal as well, the application is not limited thereto. In some embodiments, the column pitches 104H on the carrier substrate 100 are not necessarily the same, and the row pitches 10V on the carrier substrate 100 are not necessarily the same, either. As shown in the figures, the distance between the LED devices 102 refers to the distance between the center points of the sides of two LED devices in a specific direction, but the application is not limited thereto. The distance may also refer to the distance in the specific direction between the corresponding sides of two LED devices.

The step S02 of the manufacturing method M01 is followed by the step S04. The LED devices 102 are transferred from the carrier substrate 100 to the carrier substrate 120. The column pitch between the columns changes, but the row pitch between the rows remains unchanged. As shown in FIG. 1B, on the carrier substrate 120, the LED devices 102 are arranged into a matrix 121 having columns X21-X25 extending along a vertical direction and rows Y21-Y28 extending along a horizontal direction. For example, FIG. 1B shows that there are column pitches 124H between the columns X21 and X22 and between the columns X24 and X25, and that there are row pitches 124V between the rows Y21 and Y22 and between the rows Y27 and Y28. The step S04 makes all the column pitches 124H on the carrier substrate 120 approximately equal to one another, but the column pitches 124H on the carrier substrate 120 are greater than the column pitches 104H on the carrier substrate 100. However, the step S04 does not change the row pitches between the rows. Therefore, all the row pitches 124V on the carrier substrate 120 are substantially equal to the corresponding row pitches 104V on the carrier substrate 100.

In one embodiment, in the step S04, the LED devices are transferred column by column each time from the carrier substrate 100 to the carrier substrate 120. For example, the LED devices 102 in the column X01 on the carrier substrate 100 are transferred to the carrier substrate 120 at the same time to form column X21. Subsequently, the LED devices 102 in the column X02 on the carrier substrate 100 are transferred to the carrier substrate 120 at the same time to form column X22. All the LED devices 102 on the carrier substrate 100 can be transferred to the carrier substrate 120 in the same manner so that the sequence of the columns on the carrier substrate 100 is the same as that on the carrier substrate 120. In other words, the matrix 121 on the carrier substrate 120 is similar to the matrix 101 on the carrier substrate 100. The relative spatial positions of all the LED devices 102 are the same, but the column pitches 124H of the matrix 121 and the column pitches 104H of the matrix 101 are different. Consequently, the columns X21-X25 on the carrier substrate 120 are respectively from the columns X01-X05 on the carrier substrate 100. Nevertheless, the application is not limited thereto.

As stated above, since the LED devices 102 are transferred one column by one column, the distance between the LED devices 102 in the column X22 is the same as that between the LED devices 102 in the column X01. In other words, all the row pitches 124V are substantially equal to the corresponding row pitches 104V.

In another embodiment, in the step S04, the LED devices 102 are also transferred by one column each time from the carrier substrate 100 to the carrier substrate 120, but the sequence of the columns has been changed or has been rearranged. For example, the column X21 on the carrier substrate 120 is transferred from the column X01 on the carrier substrate 100, and the column X22 on the carrier substrate 120, which is adjacent to the column X21, is transferred from the column X03 on the carrier substrate 100, which is not adjacent to the column X01. That is, the step S04 can change not only the column pitches between the columns, but also the sequence of the columns.

The step S04 of the manufacturing method M01 is followed by the step S06. The LED devices 102 are transferred from the carrier substrate 120 to the carrier substrate 140. The distance between the rows changes, but the distance between the columns remains unchanged. As shown in FIG. 1B, on the carrier substrate 140, the LED devices 102 are arranged as a matrix 141 having columns X41-X45 extending along a vertical direction and rows Y41-Y48 extending along a horizontal direction. For example, FIG. 1B shows that there is a column pitch 144H between the columns X44 and X45, and that there is a row pitch 144V between the rows Y47 and Y48. The step S06 makes all the row pitches 144V on the carrier substrate 140 approximately equal to one another, and the row pitches 144V on the carrier substrate 140 are greater than the row pitches 124V on the carrier substrate 120. The step S06 does not change the column pitches between the columns. Therefore, all the column pitches 144H on the carrier substrate 140 are substantially equal to each another, and are approximately equal to the column pitches 124H on the carrier substrate 120.

In one embodiment, in the step S06, the LED devices 102 are transferred in one row each time from the carrier substrate 120 to the carrier substrate 140 in a one row-by-one row manner. For example, the LED devices 102 in the row Y21 on the carrier substrate 120 are transferred to the carrier substrate 140 at the same time to form the row Y41. Subsequently, the LED devices 102 in the row Y22 are transferred to form the row Y42. All the LED devices 120 on the carrier substrate 120 can be transferred to the carrier substrate 140 in the same manner so that the sequence of the rows on the carrier substrate 120 is the same as that on the carrier substrate 140. In other words, the matrix 141 on the carrier substrate 140 is similar to the matrix 121 on the carrier substrate 120. The relative spatial positions of all the LED devices are the same, but the row pitches 124V of the matrix 141 and the row pitches 104V of the matrix 121 are different. Consequently, the rows Y41-Y48 on the carrier substrate 140 are respectively from the rows Y21-Y28 on the carrier substrate 120. Nevertheless, the application is not limited thereto. In some embodiments, the step S06 can change not only the row pitches between the rows but also the sequence of the rows.

In view of the above, the step S06 is substantially the same as the step S04, except that the transfer directions are different. As a result, the step S04 changes the column pitches and the step S06 changes the row pitches.

In the manufacturing method M1 of FIG. 1A, the step S04 expands the column pitches followed by the step S06 that expands the row pitches, but the application is not limited thereto. In one embodiment, one step changes or expands the row pitches with the column pitches unchanged, and then another step changes or expands the column pitches with the row pitches unchanged.

In FIG. 1B, the column pitch 144H and the row pitch 144V on the carrier substrate 140 may be respectively an integer multiples of a pixel column pitch and a pixel row pitch on a pixel carrier substrate or a screen circuit carrier substrate. In an embodiment, the pixel column pitch may be equal to the column pitch 144H and the pixel row pitch is four times of the row pitch 144V. In other embodiments, the pixel column pitch may be several times greater than the column pitch 144H and the pixel row pitch is equal to the row pitch 144V. As such, the LED devices 102 on the carrier substrate 140 may be transferred to the pixel carrier substrate in a batch.

FIG. 1C shows a screen formed of four pixel carrier substrates 800. In the embodiments shown in FIG. 1C, the pixel carrier substrate 800 has pixels P arranged as an array. Each pixel P has three LED devices 102, 102x, and 102y that respectively generate, for example, red light, blue light, and green light. In another embodiment, each pixel P has more than three LED devices. For example, there are four LED devices respectively generating red light, blue light, green light, and cyan light. The LED devices may be arranged as a linear line in the pixel P. The linear line may be lateral, vertical, or oblique. The LED devices may be arranged into a non-linear pattern such as a triangle or a quadrangle in the pixel P. The pixel column pitch 844H of the pixel carrier substrate 800 is equal to the column pitch 144H on the carrier substrate 140, and the pixel row pitch 844V is equal to the row pitch 144V on the carrier substrate 140. The pixel column pitch 844H and the pixel row pitch 844V herein refer to the distances in specific directions between two corresponding sides of one pixel P, but the application is not limited thereto. The pixel column pitch 844H and the pixel row pitch 844V may also refer to the distances in specific directions between center points of sides of two adjacent pixels P. Accordingly, to transfer the LED devices 102 on the carrier substrate 140 to the pixel carrier substrate 800, the LED devise 102 are transferred in a batch only once from the carrier substrate 140 to the pixel carrier substrate 800 without changing the column pitches 144H and the row pitches 144V so the process speed is fast.

FIG. 1D shows a screen formed of four pixel carrier substrate 800a. The same or similar content with respect to FIGS. 1C and 1D can be found in FIG. 1C and the corresponding paragraphs, which will not be repeated herein. In the embodiments of FIG. 1D, the pixel column pitch 846H of the pixel carrier substrate 800a is equal to the column pitch 144H on the carrier substrate 140, and the pixel row pitch 846V is four times of the row pitch 144V on the carrier substrate 140. Therefore, to transfer the LED devices 102 on the carrier substrate 140 to the pixel carrier substrate 800a, only one fourth of the LED devices 102 are transferred in a batch once from the carrier substrate 140 to the pixel carrier substrate 800a without changing the column pitches 144H and the row pitches 144V so the process speed is fast. For example, all the LED devices 102 to be transferred on the carrier substrate 140 may be concomitantly placed on the pixel carrier substrate 800a by a pickup tool.

In the manufacturing method M01 of FIG. 1A, when providing the carrier substrate 100, the column pitches and the row pitches are not confined to the pixel column pitches and the pixel row pitches on the pixel carrier substrate 800. Consequently, the column pitches 104H and the row pitches 104V on the carrier substrate 100 may be minimized as much as possible to elevate the area utilization of the carrier substrate 100.

The carrier substrate 100 may be a growth substrate and the LED devices 102 are formed directly on the growth substrate. The material of the growth substrate may be Ge, GaAs, InP, Si, sapphire, SiC, LiAlO₂, GaN, AlN, and the like. In an embodiment, the materials of the carrier substrates 100, 120, and 140 may be Si, glass, sapphire, SiC, a thermal release tape, an UV release tape, a chemical release tape, a heat-resistant tape, a blue tape, and the like.

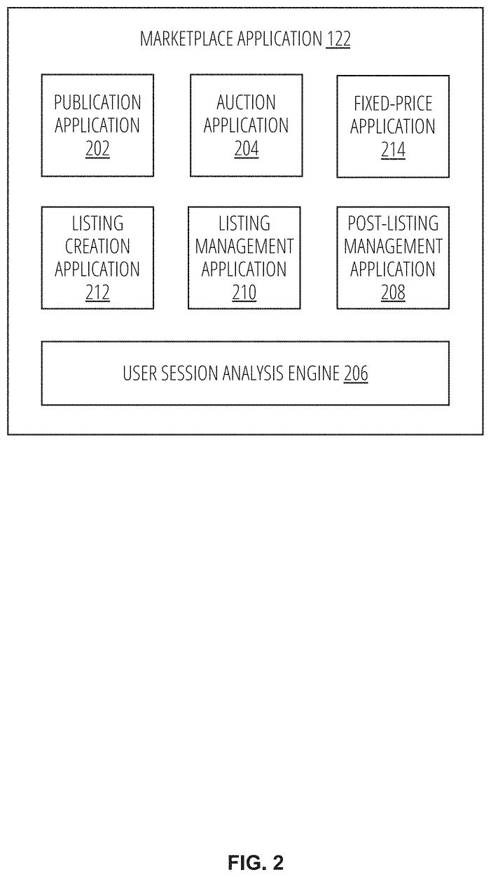

FIG. 2A shows a growth substrate 150 with a plurality of LED devices 102 formed thereon as an embodiment of the carrier substrate 100, and FIGS. 2B and 2C are cross-sectional views along the line BB and the line CC in FIG. 2A, respectively. In FIG. 2A, the LED devices 102 are completely distributed over the growth substrate 150. However, some LED devices 102 that are located on the margin of the growth substrate 150 do not have complete structures. In other embodiments, all the LED devices 102 on the growth substrate have complete structures. FIG. 2B shows the LED devices 102 are formed on the growth substrate 150, and each LED device 102 has a positive electrode 152p and a negative electrode 152n facing upward. When applying a proper voltage to the positive electrode 152p and/or the negative electrode 152n, a light-emitting layer in the LED device 102 emits light.

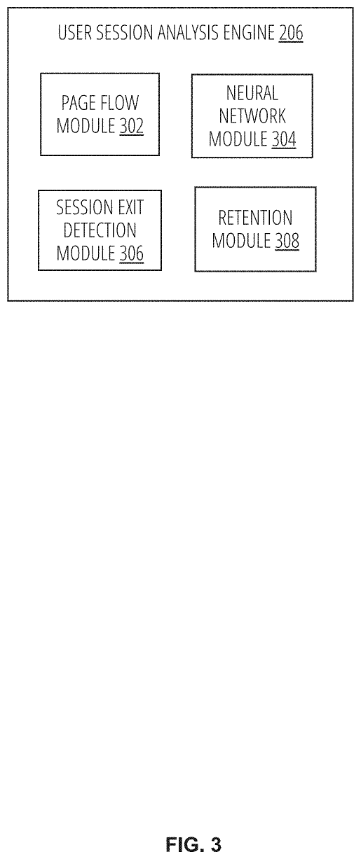

FIG. 3A shows the LED devices 102 in the exposure region 164 on the growth substrate 150 being irradiated by a laser beam. FIG. 3B shows the LED devices 102 in FIG. 2B being ablated from the growth substrate 150 because of irradiation by the laser beam and attached to the carrier substrate 160 through an adhesive layer 162. Therefore, the LED devices 102 are transferred from the growth substrate 150 to the carrier substrate 160. FIG. 3C shows the LED devices 102a in the exposure region 164 in FIG. 2C being transferred to the carrier substrate 160. In FIG. 3C, outside the exposure region 164, the LED devices 102 remain on the growth substrate 150 because a light-shielding plate 166 blocks the laser beam 168. FIGS. 3D and 3E are respectively similar to FIGS. 3B and 3C, except that no light-shielding plate 166 is present in FIGS. 3D and 3E. In FIGS. 3D and 3E, the laser beam 168 has a predetermined emission pattern similar to a linear light source, which only irradiates the LED devices 102 which are arranged in a linear line included in the exposure region 164 rather than other LED devices 102. Therefore, only LED devices 102 in the exposure region 164 are transferred to the carrier substrate 160.

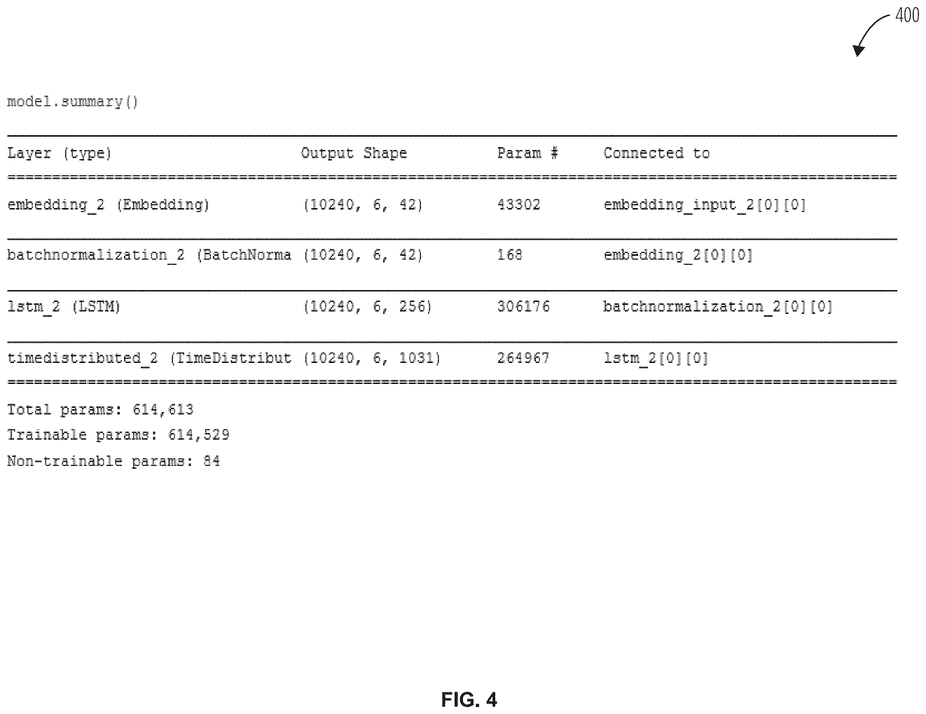

FIG. 4 shows a laser transfer apparatus A01 configured to transfer the LED devices 102 from the growth substrate 150 to the carrier substrate 160 in accordance with an embodiment of the application. The laser transfer apparatus A01 has a laser module 204, a donor stage 202, and a receiving stage 206. For example, the laser module 204 has, but is not limited to, a laser generator, a beam shaping optical system, an adjustable aperture, an optical mask, and the like, and it is configured to generate a laser beam 168 with a predetermined cutting plane pattern. For example, the laser module 168 may have an emission pattern that is similar to a linear light source. The donor stage 202 carries the growth substrate 150 and may have two-dimensional movement with respect to the laser module 204 on a predetermined plane to enable the laser beam 168 to irradiate the selected one or more LED devices 102 arranged in the array. The receiving stage 206 carries the carrier substrate 160 and may have two-dimensional movement with respect to the donor stage 202 on a predetermined plane to enable the LED devices 102 that are irradiated by the laser beam 168 to be transferred to a predetermined location on the carrier substrate 160. FIG. 4 shows that the laser module 204 provides the laser beam 168. The donor stage 202 horizontally moves the growth substrate 150 so the laser beam 168 irradiate only one column of the LED devices including an LED device 102e such that the LED device 102e and other LED devices in the same column may be readily ablated from the growth substrate 150. The receiving stage 206 horizontally moves as well to enable the LED device 102e, while being ablated along with other LED devices in the same column, to be stably attached to the location 102ee on the carrier substrate 160 through the adhesive layer 162 after being ablated. In other words, the laser transfer apparatus A01 may substantially align the laser beam 168 and the LED device 102e with the location 102ee. With the same process, FIG. 4 also shows LED devices 102b, 102c, and 102d being transferred from the growth substrate 150 to the carrier substrate 160 after being irradiated by the laser beam 168. The horizontal movement distance of the donor stage 202 each time is different from that of the receiving stage 206. Therefore, as can be seen in FIG. 4, the column pitch (or the pitch) between the LED devices 102b and 102c on the carrier substrate 160 may be greater than that on the growth substrate 150. The laser transfer apparatus A01 may realize the step S04 in FIG. 1A to change or expand the column pitch or the row pitch.

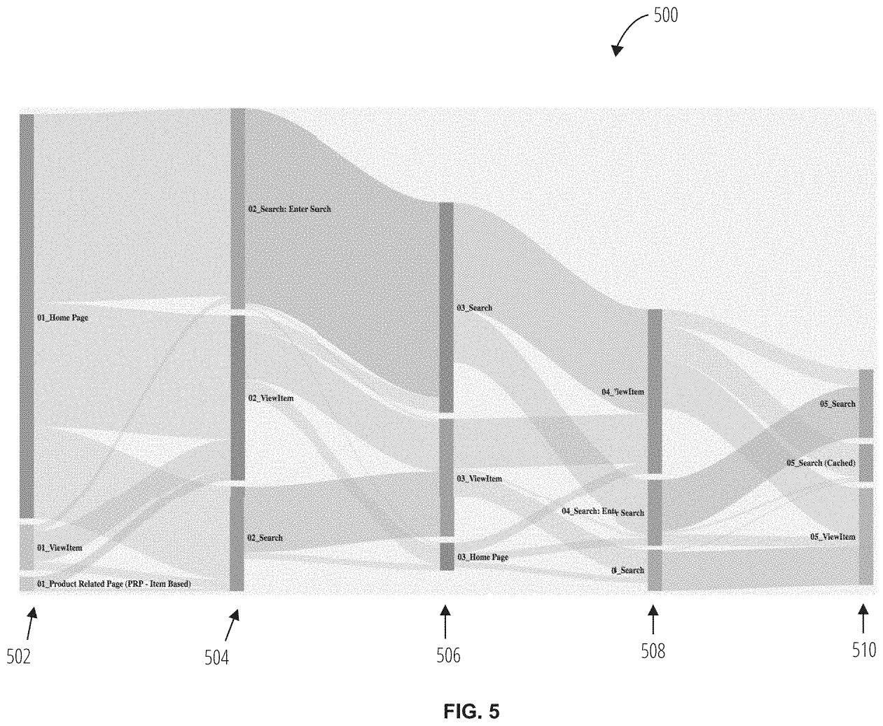

FIGS. 5A-5E show the process of transferring the LED devices 102 from the growth substrate 150 with LED devices formed thereon to the carrier substrate 160 by a pickup tool 169. In FIG. 5A, the growth substrate 150 is merely an example and is not intended to confine the scope of the application. In another embodiment of the application, the growth substrate 150 may be replaced with a carrier substrate having an adhesive layer, such as a thermal release tape, an optical release tape, a chemical release tape, a heat-resistant tape, or a blue tape.

As shown in FIGS. 5A and 5B, the pickup tool 169 adheres to one column of the LED devices 102 on the growth substrate 150. FIG. 5C shows that the LED devices 102 are ablated from the growth substrate 150 and attached to the pickup tool 169. FIG. 5D shows that the LED devices 102 are sandwiched between the pickup tool 169 and the carrier substrate 160. FIG. 5E shows that the pickup tool 169 leaves and the LED devices 102 remain and are attached to the carrier substrate 160 through the adhesive layer 162.

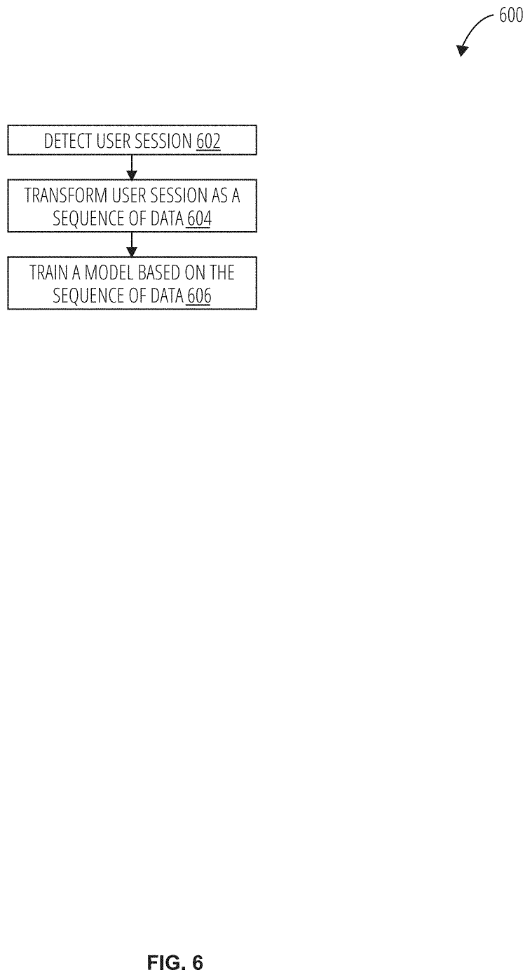

FIG. 6A shows the LED devices 102 in a certain region on the growth substrate 150 being batch transferred to a carrier substrate 180. For example, the LED devices 102 in the region 170 of the growth substrate 150 may be transferred to the carrier substrate 180 either by a laser lift-off method introduced in FIGS. 3A-3C or by the process using the pickup tool 169 introduced in FIGS. 5A-5E. The region 170 may be the biggest square on the growth substrate 150 that encompasses the complete LED devices 102, such as the biggest inscribed square in the growth substrate 150. In an embodiment, the growth substrate 150 is diced, and the LED devices 102 in the region 170 and a portion of the growth substrate 150 that underlies the LED devices 102 may be transferred simultaneously to the carrier substrate 180. As such, the carrier substrate 180 in the lower portion of FIG. 6A may be obtained after transferring several regions 170. The carrier substrate 180 may be used as the carrier substrate 100 in FIGS. 1A and 1B for transferring the LED devices twice so as to produce the carrier substrate 140 having the column pitches 144H and the row pitches 144V.

As can be seen in FIG. 6A, the LED devices 102 outside the region 170 of the growth substrate 150 may likely be wasted. FIG. 6B shows a batch transfer of the LED devices 102 in a block 172 of the growth substrate 150 to the carrier substrate 180 by, for example, laser lift-off or a pickup tool. After dicing, a portion of the growth substrate 150 may be simultaneously transferred to the carrier substrate 180 with the LED devices 102 in the block 172. After transferring the LED devices 102 in several blocks 172, the carrier substrate 180 in the lower portion of FIG. 6B may be obtained. The carrier substrate 180 may be used as the carrier substrate 100 in FIGS. 1A and 1B for transferring the LED devices twice so as to produce the carrier substrate 140 having the column pitches 144H and the row pitches 144V.

FIG. 6B also shows that two adjacent blocks 172 of the growth substrate 150 may not be adjacent after being transferred to the carrier substrate 180. That is, the relative positions of all the blocks 172 of the growth substrate 150 may be rearranged on the carrier substrate 180. It is beneficial for the LED devices 102 on the carrier substrate 180 to look like substantially uniform in visual effect. For example, on the growth substrate 150, owing to process variance, the LED devices 102 close to the left side and the right side of the growth substrate 150 may still have slight differences that can be identified by the human eye, even though the LED devices 102 do meet the manufacturing standard. If the LED devices 102 are transferred to the carrier substrate 180 in accordance with the method shown in FIG. 6A, the significant difference between the right side and the left side (a large area) is completely replicated to the carrier substrate 180 so the visual perceptible difference between the right side and the left side of the carrier substrate 180 in FIG. 6A still exists. However, according to the method shown in FIG. 6B, after the LED devices 102 are transferred to the carrier substrate 180, the blocks 172 that are originally located at different sides are likely to be mixed. Therefore, the difference between large areas can be reduced or eliminated on the carrier substrate 180 of FIG. 6B so the visual uniformity is reached accordingly.

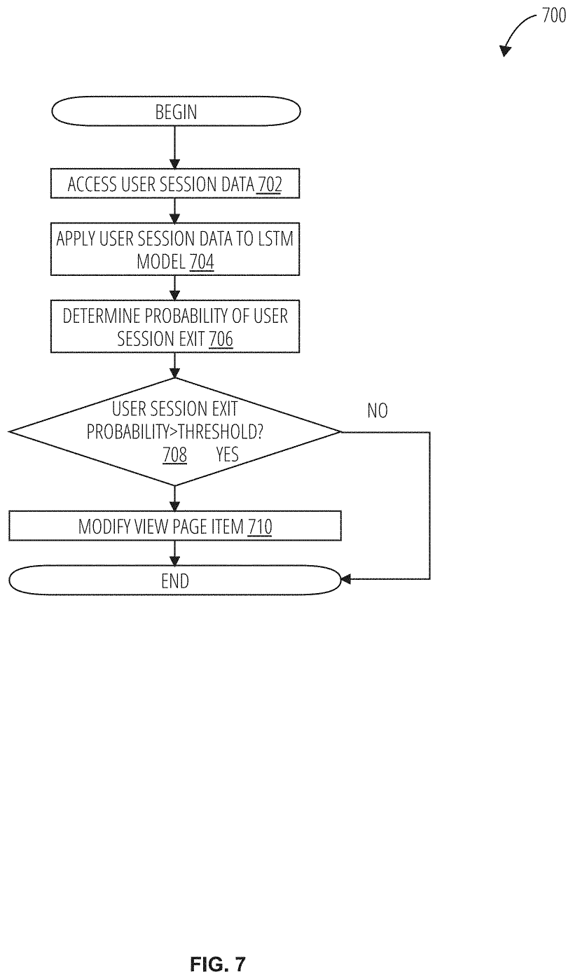

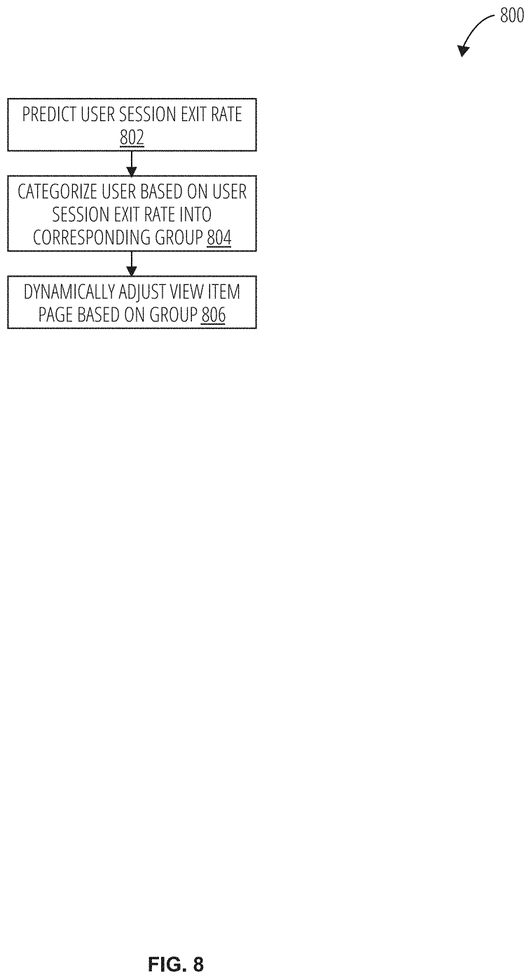

FIGS. 7A and 7B show cross-sectional views of transferring the LED devices 102 on the growth substrate 150 to a temporary substrate 190. FIG. 2B is followed by FIG. 7A, and the growth substrate 150 with the LED devices 102 in FIG. 2B is upside down and corresponding to the temporary substrate 190 with an adhesive layer 192. After being transferred to the temporary substrate 190, the positive electrodes and the negative electrodes of the LED devices 102 face downward. Next, each LED device 102 is attached to the temporary substrate 190 through the positive electrode 152p, the negative electrode 152n, and the adhesive layer 192. FIG. 7B shows that the growth substrate 150 is ablated and the LED devices 102 remain on the surface of the temporary substrate 190. FIG. 8 shows the temporary substrate 190 on which the LED devices 102 are formed as a matrix, which approximately reflects the matrix formed by the LED devices 102 on the growth substrate 150. It should be noted that, in the embodiments of FIG. 8, incomplete LED devices 102 on the growth substrate 150 are not transferred to the temporary substrate 190. In another embodiment, the incomplete LED devices 102 may be transferred to the temporary substrate 190. Next, for the temporary substrate 190 having the LED devices 102 with the electrodes facing downward, the column pitches and the row pitches may be increased by adopting the manufacturing method M01 and the aforementioned transferring methods.

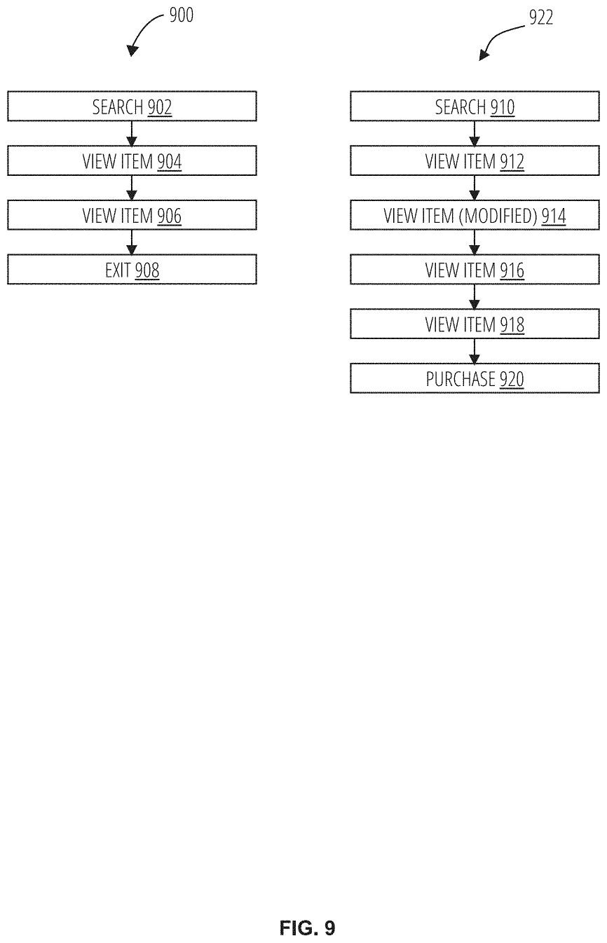

In some embodiments, the LED devices may be LED chips which are packaged. FIGS. 9A-9C show the package process of the LED devices 102 on the temporary substrate 190.

FIG. 7B is followed by FIG. 9A and a light conversion layer 193 is formed on the temporary substrate 190. For example, the light conversion layer 193 may be disposed on the temporary substrate 190 by spin coating. In an embodiment, the light conversion layer 193 is a quantum dot resist whose shape is patternable. The light conversion layer 193 may convert a blue light or an ultra-violet light entering thereof into the light with a predetermined frequency or wavelength.

FIG. 9A is followed by FIG. 9B, and a portion of the light conversion layer 193 that is between the LED devices 102 is removed by exposure and development or laser dicing to form multiple discontinuous light conversion layers 193. Each light conversion layer 193 only covers one LED device 102. In other words, FIG. 9B shows the patterning step of the light conversion layer 193.

FIG. 9B is followed by FIG. 9C, and the discontinuous light filter layers 194 may be formed by the method similar to that for the light conversion layers 193, namely by spin coating and then patterning. Each light filter layer 194 covers one light conversion layer 193 and one LED device 102. For example, the light filter layer 194 is configured to substantially block light emitted by the LED devices 102 that is not converted by the light conversion layer 193, but allow the light that is converted by the light conversion layer 193 to pass through. The LED element 102p is an LED chip further including the light filter layer 194 and the light conversion layer 193.

For example, the LED element 102p in FIG. 9C may be a green LED element. The LED device 102 may be an UV LED chip. The light conversion layer 193 is configured to convert UV light emitted by the LED device 102 into green light. The light filter layer 194 substantially blocks the UV light that is not converted by the corresponding light conversion layer 193 and passes through thereof, but allows the green light generated by the light conversion layer 193 to pass through. That is, the light filter layer 194 may prevent the leaking UV light from damaging users. LED devices with emitting colors other than the UV LED device may be utilized for the LED element 102p, and the LED element 102p may be designed to generate light rather than green light by selecting an appropriate light conversion layer 193 and an appropriate light filter layer 194.

Subsequently, the temporary substrate 190 in FIG. 9C may be used as the carrier substrate 100 in FIG. 1B. After transferring as shown in FIGS. 1A and 1B twice, the LED elements are transferred to the carrier substrate 140. There are LED elements 102p that can emit light with specific colors as shown in FIG. 9C on the carrier substrate 140.

In another embodiment, the LED elements 102p on the temporary substrate 190 in FIG. 9C may be transferred to the carrier substrate 180 first by the method in FIG. 6A or 6B. The carrier substrate 180 may be used as the carrier substrate 100 in FIGS. 1A and 1B. After transferring the LED elements twice, the carrier substrate 140 is produced.

The methods of FIGS. 9A-9C may be used to rapidly and massively produce the LED elements 102p having the light filter layers 194 and the light conversion layers 193.

The production of the LED elements 102p having the light filter layers 194 and the light conversion layers 193 on the temporary substrate 190 may save the usage amount of the light filter layer 194 and the light conversion layer 193. As explained above, owing to the transfer of the LED devices twice as shown in FIGS. 1A and 1B, the row pitches and the column pitches between the LED elements 102p in FIG. 9C are not confined by the pixel column pitches and the pixel row pitches on the pixel carrier substrate, and may be minimized as much as possible. In other words, the adjacent LED elements 102p in FIG. 9C only need a distance small enough to prevent the adjacent LED elements 102p from being connected by the residual of the light filter layer 194 and light conversion layer 193 from the removal processes. Accordingly, the consumption of the light filter layer 194 and the light conversion layer 193 for producing the LED elements 102p may be minimized to save the expensive light filter layer 194 and light conversion layer 193 and to lower the manufacture cost.

The LED element 102p in FIG. 9C is also applicable to a pixel package structure. The pixel package structure can be a package structure of one pixel in the screen. The pixel package structure includes three or more LED devices that can be controlled independently and emit light with different colors, such as blue LED devices, green LED devices, and red LED devices. By adopting the surface mount technology, the LED devices may be attached and bonded to a circuit substrate and covered by an encapsulation layer.

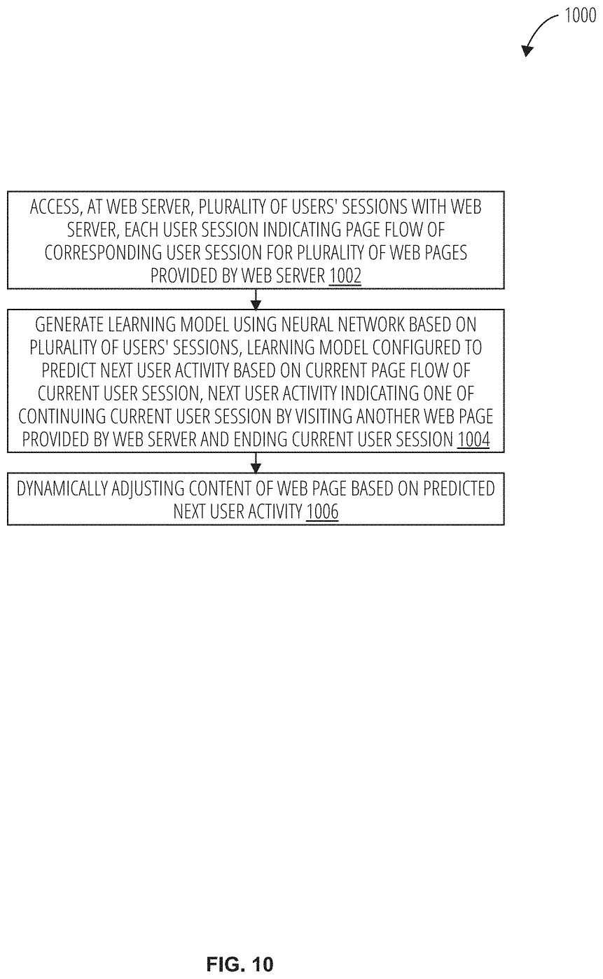

FIG. 10A shows a pixel package structure 500a. The pixel package structure 500a includes a blue LED element 102B, a green LED element 102G, and a red LED element 102R, and all of which are fixed to a circuit substrate 504 by surface mount technology. The circuit substrate 504 has metal wires 506 that change the location to which the LED elements 102B, 102G, and 102R are electrically connected. The pixel package structure 500a also has a transparent encapsulation layer 502 that protects the LED elements 102B, 102G, and 102R from being damaged by ambient humidity. The LED devices 102B, 102G, and 102R may be manufactured by the methods of FIGS. 7A-9C. For example, the green LED element 102G has a UV LED chip 102v, a light conversion layer 193G, and the light filter layer 194. The green quantum dots in the light conversion layer 193G are used to convert UV light emitted by the UV LED chip 102v and to generate green light. The light filter layer 194 substantially blocks the UV light emitted by the UV LED chip 102v. In FIG. 10A, the LED elements 102B, 102G, and 102R differ in that they have different light conversion layers. The light conversion layer 193G of the green LED element 102G is configured to generate green light, the light conversion layer 193B of the blue LED element 102B is configured to generate blue light, and the light conversion layer 193R of the red LED element 102R is configured to generate red light.

FIG. 10B shows a pixel package structure 500b. The same or similar content with respect to FIG. 10A can be referred to the previous description and the corresponding figures. The pixel package structure 500b includes a blue LED element 102BL, a green LED element 102G, and a red LED element 102R. The blue LED element 102BL is an un-packaged blue LED chip 102b1 that is not covered by the light conversion layer and the light filter layer. In FIG. 10B, the blue LED chips 102b1 are used in the green LED element 102G and red LED element 102R as light sources. Accordingly, for example, quantum dots in the light conversion layer 193G may convert blue light into green light, and the light filter layer 194 is configured to block leaking blue light that is not converted by the light conversion layer 193G. Quantum dots in the light conversion layer 193R may convert blue light into red light, and the light filter layer 194 is configured to block leaking blue light that is not converted by the light conversion layer 193R. Compared with the pixel package structure 500a, the pixel package structure 500b has an additional opaque light-shielding layer 508. The surface of the light-shielding layer 508 is substantially close to or aligned with the surface of the blue LED element 102BL. The light-shielding layer 508 may prevent the blue light emitted by the blue LED element 102BL from entering the adjacent green LED element 102G and red LED element 102R to cause them emit light.

To prevent crosstalk between the LED devices, the light-shielding layer 508 in FIG. 10B, which is formed between the encapsulation layer 502 and the circuit substrate 504 and to isolate the LED elements 102BL, and the LED elements 102G and 102R, may also be adopted in the pixel package structure 500a in FIG. 10A.

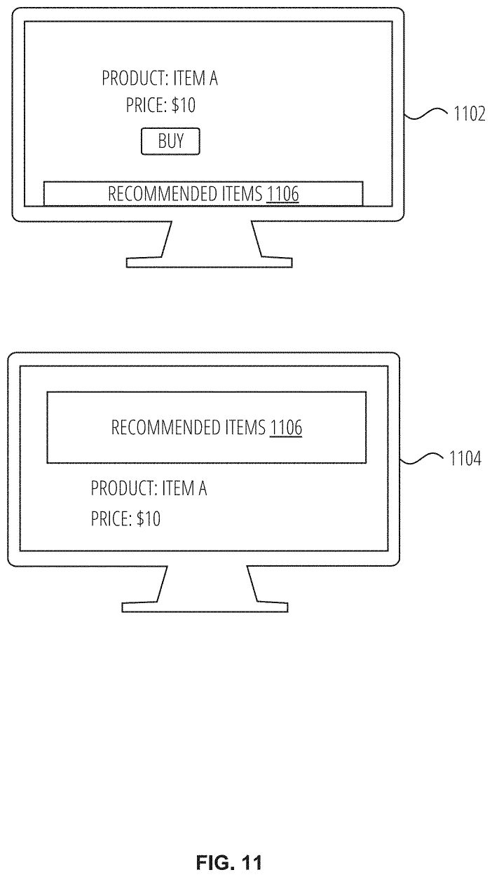

FIG. 11 shows a pixel package structure 500c. The same or similar content with respect to FIGS. 10A and 10B can be referred to the previous description and the corresponding figures. In contrast to the pixel package structures 500a and 500b, the light conversion layers 193G, 193R, and 193B used in the green LED element 102G, the red LED element 102R, and the blue LED element 102B in the pixel package structure 500c do not cover the UV LED chips 102v completely, but cover only the upper surfaces of the UV LED chips 102v. In FIG. 11, the sidewalls of the UV LED chips 102v are covered by the light-shielding layer 508.

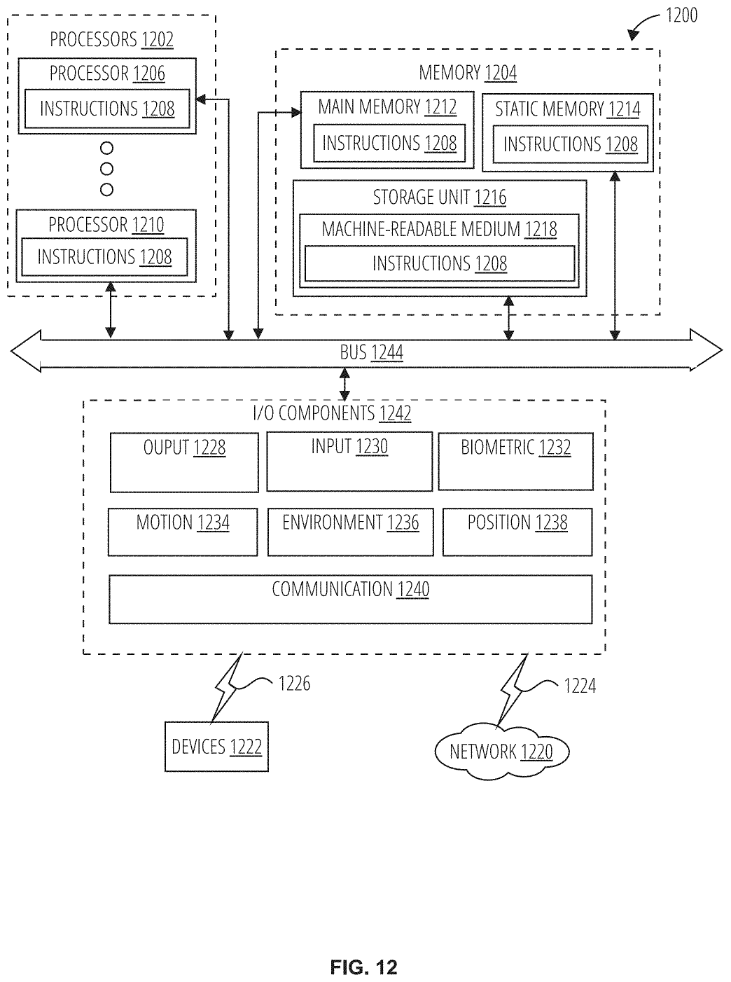

The following content will explain how the light conversion layers 193G, 193R, and 193B are wasted during the production of the pixel package structure 500c compared to the production of the pixel package structures 500a and 500b. FIGS. 12A-12C are cross-sectional views of the pixel package structure 500c during the manufacturing process. The content that is similar to or the same as those of FIGS. 10A and 10B can be referred to the previous description and the corresponding figures.

FIG. 12A shows that three openings 510G, 510R, and 510B are formed in the light-shielding layer 508 and on three UV LED chips 102v. For example, the light-shielding layer 508 may be coated on the UV LED chips 102v, and then the light-shielding layer 508 that is above the UV LED chips 102v is removed by local etching to form the openings 510G, 510R, and 510B. In addition to the coating process, a whole light-shielding layer 508 may be disposed above the UV LED chips 102v by a compressing process.

FIG. 12B shows coating the light conversion layer 193G uniformly on the structure of FIG. 12A to fill the openings 510G, 510R, and 510B. For example, the light conversion layer 193G is a quantum dot resist. FIG. 12C shows that only a portion of the light conversion layer 193G which is filled into the opening 510G remains after exposure and development processes. Other portion of the light conversion layer 193G is removed. FIGS. 12B and 12C demonstrate how the opening 510G is filled with the light conversion layer 193G. Similarly, the opening 510R may be filled with the light conversion layer 193R and the opening 510B may be filled with the light conversion layer 193B in the same method. Afterwards, as shown in FIG. 12D, portions of the light conversion layers 193G, 193R, and 193B that protrude from the openings 510G, 510R, and 510B may be removed by polishing so that the light conversion layers 193G, 193R, and 193B and the light-shielding layer 508 could be coplanar (not shown). Next, the light filter layer 194 and the encapsulation layer 502 are coated to complete the pixel package structure 500c.

Referring to FIG. 12C, the utilization rate σ of the light conversion layer 193G may be defined as the quotient of the surface area 532G of the remaining light conversion layer 193G in FIG. 12C and the whole surface area 530 of the pixel package structure 500c in FIG. 12C measured from a top-view. In view of practice, compared to the whole surface area 530 of the pixel package structure 500c, since the area of the green LED element 102G is very small, the utilization rate σ of the light conversion layer 193G in FIG. 12C may be only about 2%. In FIG. 12C, over 90% of the expensive quantum dot resist is wasted. It is unfavorable for the cost of mass production of the pixel package structure.

In FIG. 9B, the utilization rate σ′ of the light conversion layer 193 may be defined as the quotient of the upper surface area of the remaining light conversion layer 193 in FIG. 9B and the whole upper surface area of the temporary substrate 190 in FIG. 9B measured from a top-view. In FIG. 9B, the unit area 130 of the LED device is equal to the sum of the net area 130C of the device and the area of the isolation region 130T. In FIG. 9B, the utilization rate σ′ of the light conversion layer 193 may be approximately equal to the quotient of the net area 130C of the device and the unit area 130 of the LED element. In view of practice, the utilization rate σ′ of the light conversion layer 193 in FIG. 9B may be higher than 70%, which is much higher than the utilization rate σ of 2% of the light conversion layer 193G in FIG. 12C, and the production cost can be decreased dramatically. Accordingly, in term of the production cost, it is advantageous to adopt the method in FIGS. 9A-9C to massively produce the pixel package structures 500a and 500b in FIGS. 10A and 10B.

In an embodiment, a rough surface may be formed on the growth substrate 150 first, and the resulting LED devices may have a rough light-emitting surface accordingly. FIG. 13A shows the formation of LED devices 102z on a growth substrate 150x that is pre-treated to form a rough surface formed of recesses. The content in FIG. 13A that is similar to or the same as that in FIG. 2A can be referred to the previous description and the corresponding figures. FIG. 13B shows a pixel package structure 500d, whose structure similar to or the same as that of FIG. 10A can be referred to the previous description and the corresponding figures. In brief, the pixel package structure 500d adopts the LED devices 102z in FIG. 13A as the main light source. The LED devices 102z have rough light-emitting surfaces 144, which can enhance light extraction efficiency of the LED devices 102z. That is, the amount of light emitted from the light-emitting layer of the LED device 102z and then extracted through the rough light-emitting surface 144 may increase. The rough light-emitting surfaces 144 of the LED devices 102z may also enhance adhesion of the light conversion layer 193G, 193R, and the light filter layer 194 in FIG. 13B to the LED devices 102z. In an embodiment, the dimension of the rough structure of the rough light-emitting surfaces 144 may be greater than the emission wavelength of the LED devices 102z. A portion of the light from the LED devices 102z may penetrate the rough light-emitting surfaces 144, whereas another portion of the light may be reflected by the rough light-emitting surfaces 144 and become diffused light at two sides of the rough light-emitting surfaces 144.

In summary, the foregoing discloses the embodiments of the application, but it does not intend to limit the application. Those skilled in the art may make various changes, substitutions and alterations herein without departing from the spirit and scope of the present disclosure. Therefore, the scope of the application shall be defined and protected by the following claims and their equivalents.

What is claimed is:

1. A method for manufacturing an optoelectronic product, comprising:
providing a first carrier substrate;
providing a plurality of electronic devices disposed on the first carrier substrate and arranged as a first matrix, and the first matrix comprising:
a plurality of first columns extending along a first direction and a plurality of first rows extending along a second direction, wherein two adjacent of the first columns are separated from each other by a first column pitch, and two adjacent of the first rows are separated from each other by a first row pitch;
transferring a first portion of the electronic devices from the first carrier substrate to a second carrier substrate and arranging the electronic devices as a second matrix, and the second matrix comprising:
a plurality of second columns extending along the first direction and a plurality of second rows extending along the second direction, wherein two adjacent of the second columns are separated from each other by a second column pitch that is equal to the first column pitch, and two adjacent of the second rows are separated from each other by a second row pitch that is greater than the first row pitch; and
transferring a second portion of the electronic devices from the second carrier substrate to a third carrier substrate and arranging the electronic devices as a third matrix, and the third matrix comprising:
a plurality of third columns extending along the first direction and a plurality of third rows along the second direction, wherein two adjacent of the third columns are separated from each other by a third column pitch that is greater than the second column pitch, and two adjacent of third rows are separated from each other by a third row pitch that is equal to the second row pitch.

2. The method of claim 1, wherein the step of transferring the first portion of the electronic devices from the first carrier substrate to the second carrier substrate is to transfer the electronic devices to the second carrier substrate in a one first row-by-one first row manner to form the second rows.

3. The method of claim 2, wherein there is a first row sequence among the first rows, and there is a second row sequence among the second rows equal to the first row sequence.

4. The method of claim 2, wherein the step of transferring the second portion of the electronic devices from the second carrier substrate to the third carrier substrate is to transfer the electronic devices to the third carrier substrate in a one second column-by-one second column manner to form the third columns, wherein the second portion can be equal to or not equal to the first portion.

5. The method of claim 4, wherein there is a second column sequence among the second columns, and there is a third column sequence among the third columns equal to the second column sequence.

6. The method of claim 2, further comprising:
transferring a third portion of the electronic devices from the third carrier substrate to a pixel carrier substrate and arranging the electronic devices as a pixel matrix, and the pixel matrix comprising:
a plurality of pixel columns along the first direction and a plurality of pixel rows along the second direction, wherein two adjacent of the pixel columns are separated by a pixel column pitch that is a first positive integer multiple of the third column pitch, and two adjacent of the pixel rows are separated by a pixel row pitch that is a second positive integer multiple of the third row pitch.

7. The method of claim 1, wherein the electronic devices are light-emitting diode (LED) elements, laser diodes, photodiodes, or integrated circuit components.

8. The method of claim 7, wherein each of the LED elements comprises an LED chip and a light conversion layer covering the LED chip.

9. The method of claim 8, wherein the LED chip comprises a plurality of light-emitting regions connected in series, in parallel, or in parallel and series.

10. The method of claim 8, wherein each of the LED elements further comprises two electrodes located on a same side of the LED chip.

11. The method of claim 1, wherein the first carrier substrate is a growth substrate selected from Ge, GaAs, InP, Si, sapphire, SiC, LiAlO₂, GaN, or AlN.

12. An apparatus for performing the step of transferring in the method of claim 1, comprising:
a laser module configured to generate a laser beam with a predetermined emission pattern;
a donor stage configured to support the first carrier substrate and the plurality of electronic devices on the first carrier substrate, wherein the laser module and the donor stage are configured to allow relative movement, thereby enabling the laser beam to irradiate the first portion of the electronic devices among the electronic devices; and
a receiving stage configured to support the second carrier substrate, wherein the donor stage and the receiving stage are configured to allow relative movement, thereby enabling the first portion of the electronic devices to be transferred to predetermined positions on the second carrier substrate.

13. The apparatus of claim 12, further comprising a light-shielding plate blocking the laser beam to form the predetermined emission pattern.

14. The apparatus of claim 12, wherein the laser module further comprises a laser generator and a beam shaping optical system.

15. The apparatus of claim 12, wherein the laser beam comprises a linear predetermined emission pattern.

16. A method for manufacturing LED devices, comprising:
providing a growth substrate with LED chips formed thereon;
transferring the LED chips from the growth substrate to a temporary substrate;
forming a light conversion layer on the temporary substrate, wherein the light conversion layer covers the LED chips and is configured to convert a first light emitted from the LED chips into a second light with a predetermined wavelength;
patterning the light conversion layer;
forming a light filter layer on the light conversion layer, wherein the light filter layer covers the light conversion layer and the LED chips and is configured to block the first light; and
patterning the light filter layer such that each LED device comprises a portion of the light conversion layer, the light filter layer, and one of the LED chips.

17. The method of claim 16, further comprising pre-treatment of the growth substrate to form recesses on the LED chips.

18. The method of claim 17, wherein a dimension of the recesses is greater than an emission wavelength of the LED chips.

19. The method of claim 16, wherein the light conversion layer has a utilization rate σ′ higher than 70%.

20. The method of claim 19, wherein the light conversion layer is a patternable quantum dot resist layer.
